(19) United States
(12) Patent Application Publication
(10) Pub. No.: US 2009/0319207 A1
(43) Pub. Date: Dec. 24, 2009

(54) ELECTRICAL INSTALLATION ARRANGEMENT

(75) Inventor: MICHAEL KOCH, Wien (AT)

Correspondence Address: HENRY M FEIEREISEN, LLC;HENRY M FEIEREISEN, 708 THIRD AVENUE, SUITE 1501, NEW YORK, NY, 10017, US

(73) Assignee: Moeller Gebaudeautomation GmbH, Schrems (AT)

(21) Appl. No.: 12/486,247

(22) Filed: Jun. 17, 2009

Related U.S. Application Data
(60) Provisional application No. 61/073,534, filed on Jun. 18, 2008.

(30) Foreign Application Priority Data
Jun. 18, 2008 (AT) A 975/2008

(51) Int. Cl. G01R 31/00; G01R 31/08

(52) U.S. Cl. 702/58; 324/512

(57) ABSTRACT

An electrical installation arrangement includes an electrical power distribution network and/or at least one first electrical device. In order to reduce complexity of electrical installation arrangement and increase safety of people and facilities, a detector is provided for determining a fault source using blind source separation, e.g. for locating at least one first electrical fault source, in particular at least one first fault current source and/or a first overload area. The detector is hereby disposed on and/or in the electrical power distribution network and/or the at least one first electrical device.

### CROSS-REFERENCES TO RELATED APPLICATIONS

This application claims the benefit of prior filed U.S. provisional Application No. 61/073,534, filed Jun. 18, 2008, pursuant to 35 U.S.C. 119(e), the content of which is incorporated herein by reference in its entirety as if fully set forth herein.

This application also claims the priority of Austrian Patent Application, Serial No. A 975/2008, filed Jun. 18, 2008, pursuant to 35 U.S.C. 119(a)-(d.

### BACKGROUND OF THE INVENTION

The present invention relates to an electrical installation arrangement.

The following discussion of related art is provided to assist the reader in understanding the advantages of the invention, and is not to be construed as an admission that this related art is prior art to this invention.

Electrical installation arrangements are known, in which a plurality of electrical devices and/or consumers are situated. To protect these facilities and/or the people who are located in the area of these facilities, a plurality of individual protective units is provided, in particular ground fault interrupters and/or line circuit breakers. The electrical installation arrangement is divided into individual partial networks, which each are protected separately, usually by an array of different circuit breakers. Known electrical installation arrangements of this type have the disadvantage that a very large number of circuit breakers are necessary in order to ensure the safety of all partial networks. In addition, they have the further disadvantage that a determination of a fault source is not possible. A partial network which has an electrotechnical fault is deactivated, however, the following fault search is very time-consuming and must be performed by a technician in many cases. A subsequent detection of a fault source is often not possible even by a technician, so that the partial network which was previously shut down as faulty usually must be put back into operation unchanged, well knowing that there is a potential fault source within this partial network. Endangerment of people and facilities is consciously accepted by this not unusual behavior.

It would therefore be desirable and advantageous to provide an improved electrical installation arrangement which obviates prior art shortcomings and which is simple in construction while yet enhancing safety of people and facilities.

### SUMMARY OF THE INVENTION

According to one aspect of the present invention, an electrical installation arrangement includes at least one member selected from the group consisting of an electrical power distribution network and an electrical device, and a detector disposed on the member for determining a fault source using blind source separation.

A protection of people and facilities, above all in complex electrical installation arrangements, may thus be implemented with little installation and device outlay.

A fault in a complex electrical installation arrangement may thus be detected and/or localized with little installation outlay. Finding an electrotechnical fault within an electrical installation arrangement is thus not only simplified, but rather is performed by the electrical installation arrangement itself. A user may then simply remedy the detected fault. This may prevent faulty electrical installation arrangements from being put back into operation unchanged without knowing the cause of a fault. The safety of people and facilities may thus be increased.

According to another aspect of the present invention, a fault determination device for determining a fault source in an electrical installation arrangement includes a sensor input, a control output for at least indirect activation of a disconnection contact within the electrical installation arrangement, and a data processing unit for determining a fault source in the electrical installation arrangement using blind source separation.

According to still another aspect of the present invention, a method for determining a fault source in an electrical installation arrangement, using blind source separation, includes the steps of detecting first and second physical variables induced and/or influenced by the electrical installation arrangement, and determining a fault source from the first and second physical variables using blind source separation.

### BRIEF DESCRIPTION OF THE DRAWING

Other features and advantages of the present invention will be more readily apparent upon reading the following description of currently preferred exemplified embodiments of the invention with reference to the accompanying drawing, in which:

FIG. 1 shows a first embodiment of an electrical installation arrangement according to the present invention; and

FIG. 2 shows a second embodiment of an electrical installation arrangement according to the present invention.

### DETAILED DESCRIPTION OF PREFERRED EMBODIMENTS

Throughout all the figures, same or corresponding elements may generally be indicated by same reference numerals. These depicted embodiments are to be understood as illustrative of the invention and not as limiting in any way. It should also be understood that the figures are not necessarily to scale and that the embodiments are sometimes illustrated by graphic symbols, phantom lines, diagrammatic representations and fragmentary views. In certain instances, details which are not necessary for an understanding of the present invention or which render other details difficult to perceive may have been omitted.

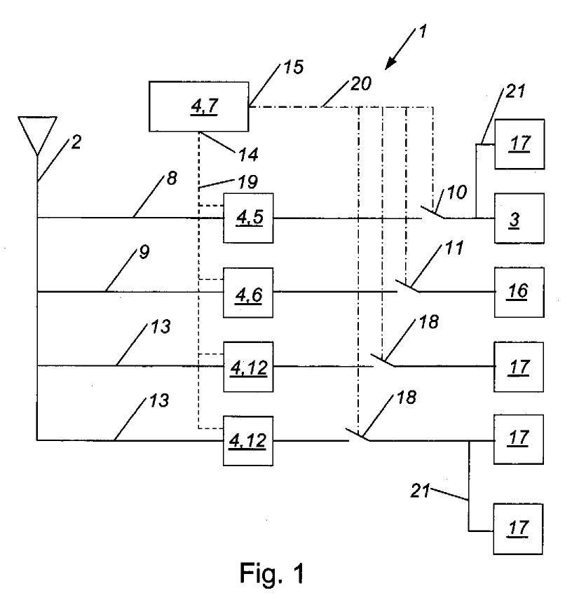

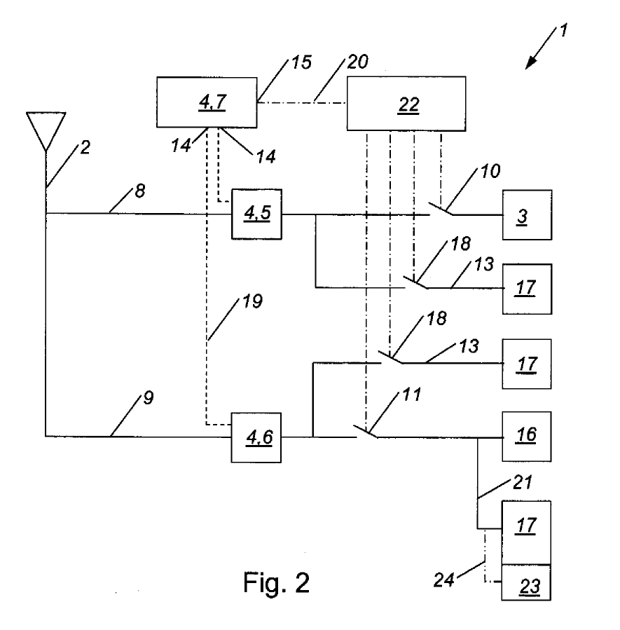

FIGS. 1 and 2 show two embodiments of an electrical installation arrangement, generally designated by reference numeral 1. The electrical installation arrangement includes an electrical power distribution network 2 and/or at least one electrical device 3. A detector 4 for determining a fault source using blind source separation is situated on and/or in the electrical power distribution network 2 and/or the least one first electrical device 3, preferably for locating at least one first electrical fault source, in particular at least one first fault current source and/or one first overload area.

The electrical power distribution network 2 has at least one first electrical partial network 8 and one second electrical partial network 9 for connecting electrical consumers and/or electric devices 3, and at least one first sensor 5 and one second sensor 6 for detecting at least one first physical variable which is induced and/or may be influenced by the electrical installation arrangement 1. The first electrical partial network 8 has first pre-definable activatable disconnection contacts 10, and the second electrical partial network 9 has second pre-definable activatable disconnection contacts 11. The first and the second sensors 5, 6 are connected to a fault determination device 7 which is constructed to determine a fault source in the electrical installation device 1 using blind source separation and is operationally linked to the first and the second disconnection contacts 10, 11.

A protection of people and facilities, in particular in complex electrical installation arrangements 1, can thus be implemented with little installation and device outlay. A fault in a complex electrical installation arrangement 1 can thus be detected and/or localized with little installation outlay. Finding an electrotechnical fault within an electrical installation arrangement 1 is thus not only simplified, but rather is performed by the electrical installation arrangement 1 itself. A user may then simply remedy the detected fault. This may prevent faulty electrical installation arrangements 1 from being put back into operation unchanged without knowing the cause of a fault. The safety of people and facilities can thus be increased.

Electrical installation arrangements 1 according to the invention are provided for the operation of any type of electrical power distribution network 2. In particular, they are provided for electrical power distribution networks 2, in particular for complex power distribution networks 2 in industrial facilities, for example, which are operated in Europe using a voltage of 230 V/400 V, for example.

Electrical devices 3 and/or other consumers may be disconnected from the electrical power distribution network 2 by electrical installation arrangements 1 according to the invention and therefore shut down and/or deactivated, and/or entire partial networks 8, 9, 13, therefore partial areas of an electrical power distribution network 2, may be turned off. As shown in FIGS. 1 and 2, the partial area of the electrical power distribution network 2 which can be shut down by disconnection contacts 10, 11, 18 and disconnected from the electrical power distribution network 2 in this way is referred to as a partial network 8, 9, 13. In the non-limiting example shown in FIGS. 1 and 2, it is provided that the electrical power distribution network 2 has at least one first electrical partial network 8 and one second electrical partial network 9 for connecting electrical devices 3, the first electrical partial network 8 having first pre-definable activatable disconnection contacts 10, and the second electrical partial network 9 having second pre-definable activatable disconnection contacts 11. Furthermore, it may be provided according to the illustrated preferred embodiments of the present invention that the partial networks 8, 9, 13, which can be shut down per se, are subdivided still further into so-called subnetworks 21, an area within a partial network 8, 9, 13, to which electrical devices 3, 16, 17 are connected and/or are connectable being referred to as a subnetwork 21, and this subnetwork 21 not being implemented as disconnectable per se from the electrical power distribution network 2 separately using separate disconnection contacts 10, 11, 13. According to the illustrations of FIGS. 1 and 2, electrical devices 3, 16, 17 are connected to each partial network 8, 9, 13 and/or to each subnetwork 21. For this purpose, it is noted that only the capability for connecting electrical devices 2, 16, 17 to a partial network 8, 9, 13 and/or subnetwork 21 may also be provided.

The electrical power distribution network 2, the partial networks 8, 9, 13, and subnetworks 21 are each schematically shown as a single line in FIGS. 1 and 2, this single line also comprising all electrical lines of the particular electrical power distribution network 2, partial network 8, 9, 13, and/or subnetwork 21, and therefore preferably representing two, three, four, or five electrical lines or cables.

Any type of a disconnection contact 10, 11, 18, which is capable of turning off a network, thus partial network 8, 9, 13 and/or subnetwork 21, under the maximum electrical states to be expected, thus from the electrical power distribution network 2, may be provided as the disconnection contacts 10, 11, 18. The maximum electrical states to be expected are preferably understood to include the maximum current flow to be expected, the maximum voltage to be expected, and/or the maximum conduction to be expected. In addition to the actual maximum electrical states to be expected in an electrical power distribution network 2, the states may also be predetermined by relevant norms and/or guidelines. Thus, for example, in an electrical power distribution network 2 having an operating voltage of 240 V, it may be provided that the disconnection contacts 10, 11, 18 must be able to reliably shut down currents at a level of up to 10,000 A, which is possible in using the disconnection switches known to those skilled in the art, as are implemented, for example, in known ground fault interrupters, line circuit breakers, and/or power circuit breakers.

It is provided that the disconnection contacts 10, 11, 18 disconnect the particular partial network 8, 9, 13 from the electrical power distribution network 2. For this purpose, it may be considered to be sufficient to situate a disconnection contact 10, 11, 18 only in the particular current-conducting outer cable or phase. Also situating a disconnection contact 10, 11, 18 in the neutral cable is preferably provided, also implementing the ground cable as switchable using a disconnection contact 10, 11, 18 further being able to be provided.

The disconnection contacts 10, 11, 18 are implemented at least for the remote-controlled opening of their partial networks 8, 9, 13, preferably a cable-bound or optical-fiber-bound remote control or activation being provided, whereby a low susceptibility to malfunction may be achieved above all in environments having strong electromagnetic interference fields. However, it may also be provided that the disconnection contacts 10, 11, 18 have a radio interface for shutdown by radio remote control, a high degree of interference resistance also being able to be achieved by suitable channel coding methods. The installation outlay may be significantly reduced by activation using radio, both raw materials for the control lines 20 and also work time being able to be saved. Above all in times of ever increasing raw material costs, the total cost outlay for an electrical power distribution network may be significantly reduced in this way. It may preferably be provided that the disconnection contacts 10, 11, 18 are also implemented for the pre-definable remote-controlled turning-on of the particular partial networks 8, 9, 13, known configurations for turning on switching devices by remote control, such as circuit breakers, being able to be provided for this purpose.

In accordance with the invention, a detector 4 for determining a fault source using blind source separation is situated on and/or in the electrical power distribution network 2 and/or the at least one first electrical device 3. A fault is preferably any type of fault whose action within an electrical power distribution network 2 may be established, the occurrence of a fault current and/or an excess current, such as a short-circuit current, and/or an overvoltage or undervoltage preferably being referred to as a fault. The particular cause of the particular fault is referred to as the fault source, therefore the origin of the fault within the electrical power distribution network 2. The determination of a fault source preferably refers to the establishment of the type of the fault and the localizing of the fault source, in particular at least one first fault current source and/or a first overload area, within the electrical power distribution network 2.

The detector 4 for determining a fault source using blind source separation includes at least one first sensor 5 and one second sensor 6 for detecting at least one first physical variable which is induced and/or may be influenced by the electrical installation arrangement 1, such as a voltage, a current, in particular a fault current and/or excess current, and/or a temperature. The first sensor 5, second sensor 6, and/or further sensor 12 are therefore implemented in particular as a current sensor, in particular as a shunt, Hall element, transformer, differential current transformer, or cumulative current transformer, and/or thermocouple. Currently preferred is the configuration of the respective sensor 5, 6, 12 as very broadband, for the purpose of picking up the particular physical variable as a frequency-dependent and/or time-dependent signal, with this signal particularly being picked up over a wide frequency range. The safety of people and facilities may thus be ensured, without performing unnecessary shutdowns of individual partial networks for their safety, because the effect of the electrical current on people or useful animals is strongly frequency-dependent, while the corresponding limiting values for facility protection are essentially a function of the frequency-independent thermal action of the electrical current. Reference is made to the relevant norms and publications, for example, by Prof. Biegelmeier, in regard to the different limiting values for the protection of people, useful animals, and facilities, i.e., machines and buildings.

Preferably, it is provided that the first sensor 5 is situated on and/or in the first electrical partial network 8 and/or the first electrical device 3, and the second sensor 6 is situated on and/or in the second electrical partial network 9 and/or a second electrical device 16, whereby a detection of a fault within the electrical power distribution network 2 is possible. As explained in greater detail hereafter, a configuration of a sensor 5, 6, 12 in each individual partial network 8, 9, 13 is not necessary, therefore, it may be provided that at least one partial network 8, 9, 13 is implemented as sensor-free. The individual sensors 5, 6, 12 may be situated, for example, in the immediate surroundings of the particular closest disconnection contacts 10, 11, 18, as widely distributed as possible in the electrical installation arrangement 2, directly at the individual devices 3, 16, 17, or according to a combination of the above-mentioned variants.

The detector 4 for determining a fault source using blind source separation also includes at least one fault determination device 7 for determining a fault source in the electrical installation arrangement 1 using blind source separation. Blind source separation is a method for determining a single signal and assigning this signal to a signal source within a signal mixture of manifold different signals of different signal sources. A condition for the correct function of blind source separation is that the individual signals, which form the signal mixture together, are linearly independent from one another, and the signal mixture is picked up and/or detected at at least two different points each having different transmission distances from the signal source to the relevant point. Currently, various methods are known for blind source separation, such as principal component analysis, singular value decomposition, independent component analysis, dependent component analysis, nonnegative matrix factorization, and/or low complexity coding and decoding, in the present case, for example, an implementation in accordance with independent component analysis preferably being provided.

In this context, it is preferably provided in a refinement of the invention that further methods are provided for implementing the blind source separation, in particular methods in which the number of the possible fault sources, therefore in the present invention the number of the electrical devices 3, 16, 17 and/or partial networks or subnetworks 8, 9, 13, 21, is less than the number of the sensors 5, 6, 12 to be provided, whereby the installation outlay may be reduced further. Specifically, especially preferred methods of this type are known, for example, from Andrzej Cichocki and Shun-ichi Amari. An electrical installation arrangement 2 may thus be formed, in which the total number of the sensors 5, 6, 12 is less than the total number of the electrical partial networks 8, 9, 13, whereby the outlay for forming an electrical installation arrangement 2 may be reduced further, in particular in relation to the prior art, in which each partial network 8, 9, 13 is secured by separate autonomous safety switching technology. FIG. 2 shows a configuration of this type, for example, in which five potential fault sources in the form of five devices 3, 16, 17 are monitored by only two sensors 5, 6, the exact assignment of an occurring fall to a specific fault source nonetheless being possible, because an occurring fault current propagates within the entire electrical power distribution network 2, for example, and therefore a fault current occurring in the first device 3 is detected not only by the first sensor 5, but rather also by the second sensor 6.

In a method for determining a fault source in an electrical installation arrangement 1 using blind source separation, it is therefore provided that at least one first physical variable and one second physical variable, which are induced and/or may be influenced by the electrical insulation configuration 1, are detected, and subsequently a fault source is determined from the first and second physical variables using blind source separation.

In a refinement of the method according to the invention, is preferably provided that subsequently the fault source is deactivated by opening at least one disconnection contact 10, 11, 18 if the fault exceeds a pre-definable first limiting value, in order to prevent the fault from causing damage. It may be provided that a message about the occurrence of the fault is also transmitted to and/or displayed on a user terminal, in order to inform a user about the status of the electrical installation arrangement 1. Transmitting or displaying a corresponding message on or to a user terminal already before the switching of the disconnection contacts 10, 11, 18 about an imminent fault, for example, if the fault which is represented by a measured value of one of the sensors exceeds a pre-definable second limiting value, may also be provided. Thus, an imminent fault may already be reacted to, and if necessary a technician may be advised to remedy the fault, and/or the affected fault source may be manually deactivated. Furthermore, the remotely-acting adjustment of the first and second limiting values may be provided. For this purpose, it may be provided that the fault determination device 7 has the corresponding assemblies for displaying a fault, and the corresponding assemblies for transmitting a message to a user terminal, and for receiving an instruction from a user terminal, preferably in the form of a radio interface which is at least half-duplex capable.

The fault determination device 7 has at least one sensor input 14 and at least one control output 15 for at least indirect activation of at least one disconnection contact 10, 11 within an electrical installation arrangement 1, and also a data processing unit for determining a fault source in the electrical installation arrangement 1 using blind source separation. The data processing unit preferably has a microcontroller, microprocessor, and/or a field programmable gate array (FPGA), and the components necessary for their operation, such as power supply units and memory units, for example, in the form of semiconductor memories, optical memories, and/or magnetic memories. Furthermore, an input, such as a button input panel, and/or a display, such as a display screen or simple status light displays, may be provided.

The sensor input 14 is implemented for the input of the signals detected by the sensors 5, 6, 12, and may be implemented as an analog or digital input. According to FIG. 1, it is provided that the individual sensors 5, 6, 12 are situated on a sensor line 19, which is implemented as a bus and which is shown as a dashed line in FIGS. 1 and 2—so it may be differentiated better—and only the single sensor line 19 is applied to the sensor input 14. In this implementation, it is provided that bus controllers are situated on the individual sensors 5, 6, 12, and on the sensor input 14. In the embodiment of FIG. 2, a sensor input 14 is provided for each sensor 5, 6.

The control output 15 is implemented to activate the disconnection contacts 10, 11, 18, according to the embodiment of FIG. 1, the implementation of the single control line 20, which is shown as a dot-dash line in FIGS. 1 and 2—so it may be differentiated better—is provided as a bus, further activation components having been dispensed with, however. The control output 15 must deliver all of the power necessary for activating the disconnection contacts 10, 11, 18, and has a correspondingly high-powered output stage. Furthermore, in the embodiment of FIG. 2, a separate switching unit 22 is provided, which is activated by the control line 20, and then in turn performs the control of the individual disconnection contacts 10, 11, 18. This has the advantage above all in extensive electrical installation arrangements 1 that excessively great cable lengths do not occur, which could result in problems in the driver stages and/or in signal dispersion in the control lines 20.

In a refinement of the invention, a further sensor 23 for the detection of a non-electrical variable may be provided in the area of at least one device 3, 16, 17, such as a liquid and/or moisture sensor, a heat sensor, a Geiger counter, a harmful gas sensor, a fire alarm, a smoke gas sensor, an impact sensor, and/or a vibration sensor. The relevant sensor 23 is preferably implemented in such a way that, in case of a detection of a hazardous operating state, which would require a notification of a user or a shutdown of the relevant device 17, the sensor intentionally generates a pre-definable derivation current and conducts it via a derivation section 24 provided in or on the device 17 into the relevant second partial network 9 or subnetwork 21. Therefore, without a further bus connection, the relevant device 17 may be identified as faulty and shut down if needed. For this purpose, the pre-definable derivation current may be used for information transmission, in that information about the operating state and/or the sensor data in coded form are contained in the derivation current, for example, which may be read out and processed by the fault determination device 7.

Further embodiments according to the invention only have a part of the described features, any feature combination, in particular also of various described embodiments, being able to be provided.

While the invention has been illustrated and described in connection with currently preferred embodiments shown and described in detail, it is not intended to be limited to the details shown since various modifications and structural changes may be made without departing in any way from the spirit and scope of the present invention. The embodiments were chosen and described in order to explain the principles of the invention and practical application to thereby enable a person skilled in the art to best utilize the invention and various embodiments with various modifications as are suited to the particular use contemplated.

What is claimed as new and desired to be protected by Letters Patent is set forth in the appended claims and includes equivalents of the elements recited therein:

1. An electrical installation arrangement, comprising:
at least one member selected from the group consisting of an electrical power distribution network and an electrical device; and
a detector disposed on the member for determining a fault source using blind source separation.

2. The electrical installation arrangement of claim 1, wherein the fault source is selected from the group consisting of electrical fault source, fault current source, and overload area.

3. The electrical installation arrangement of claim 1, wherein the detector includes a sensor assembly detecting a physical variable induced and/or influenced by the member.

4. The electrical installation arrangement of claim 1, wherein the detector includes a fault determination device which determines the fault source.

5. The electrical installation arrangement of claim 4, wherein the electrical power distribution network includes first and second electrical partial networks for connection of a plurality of electrical devices, said first and second electrical partial networks having each pre-definable activatable disconnection contacts, wherein the sensor assembly is connected to the fault determination device, and the fault determination device is operationally linked to the disconnection contacts of the first and second electrical partial networks.

6. The electrical installation arrangement of claim 5, wherein the sensor assembly has first and second sensors, the first sensor being connected to at least one of the first electrical partial network and the electrical device, and the second sensor being situated to at least one of the second electrical partial network and a further electrical device.

7. The electrical installation arrangement of claim 1, wherein the blind source separation is implemented by independent component analysis.

8. The electrical installation arrangement of claim 1, wherein the sensor assembly has a predefined number of sensors and the electrical power distribution network includes has a predefined number of electrical partial networks, with the number of sensors being less than the umber of electrical partial networks.

9. The electrical installation arrangement of claim 6, wherein at least one of the first and second sensors is an electrical sensor.

10. The electrical installation arrangement of claim 9, wherein the electrical sensor is an element selected from the group consisting of shunt, Hall element, transformer, and cumulative current transformer.

11. The electrical installation arrangement of claim 5, wherein the fault determination device has a sensor input receiving a signal detected by the sensor assembly, a control output for at least indirect activation of the disconnection contacts of the first and second electrical partial networks in response to the signal, and a data processing unit rendered operative in response to the signal for determining the fault source.

12. A fault determination device for determining a fault source in an electrical installation arrangement, comprising:
a sensor input;
a control output for at least indirect activation of a disconnection contact within the electrical installation arrangement; and
a data processing unit for determining a fault source in the electrical installation arrangement using blind source separation.

13. A method for determining a fault source in an electrical installation arrangement, using blind source separation, comprising the steps of:
detecting first and second physical variables induced and/or influenced by the electrical installation arrangement; and
determining a fault source from the first and second physical variables using blind source separation.
